(19) United States
(12) Patent Application Publication
(10) Pub. No.: US 2026/0239916 A1
(43) Pub. Date: Aug. 13, 2026

(54) SYSTEM FOR CONTROLLING THE PROCESSING OF MICROELECTRONIC DEVICES

(71) Applicant: NOVA MEASURING INSTRUMENTS GMBH, Dresden (DE)

(72) Inventor: Jurg Stahl, Dresden (DE)

(73) Assignee: NOVA MEASURING INSTRUMENTS GMBH, Dresden (DE)

(21) Appl. No.: 19/470,740

(22) PCT Filed: Mar. 28, 2024
(86) PCT No.: PCT/EP2024/058434

§ 371 Date: Sep. 29, 2025

(30) Foreign Application Priority Data
Mar. 30, 2023 (DE) 202023101616.2

(51) Int. Cl. H10P 72/00

(52) U.S. Cl. CPC H10P 72/0604; H10P 72/0448

(57) ABSTRACT

System and devices for monitoring and controlling the processing of a microelectronic substrate are disclosed. An aspect of the device comprises one or more clusters having sealed doors. Each of the sealed doors comprise a wet parts cabinet on a front side which is divided into a plurality of clusters and occupy one or more of chemical workstations which execute analytical applications. The sealed doors comprise an electrical cabinet on a back side for controlling the operation of the workstations. The sealed doors are configured to maintain a negative pressure in the wet parts cabinet and an overpressure in the electrical cabinet. The device also comprises a chemical cabinet for storing and providing the chemicals required for analytical applications running through the workstations. An interface of the device provides connectivity with a computing device for monitoring and controlling the analytical applications.

### FIELD OF THE INVENTION

The disclosure herein relates to a system for controlling the manufacture of microelectronic substrates. In particular, a system for monitoring and controlling the processing of substrates using electrolytic and electroless techniques is described. Specifically, it is intended for applications in the semiconductor industry for analysis/control of the concentration of the processing bath components.

### BACKGROUND OF THE INVENTION

Microelectronic devices are manufactured by depositing and removing multiple layers of materials on a substrate such as a silicon wafer to produce a large number of individual devices. For example, layers of photoresist, conductive materials, and dielectric materials are deposited, patterned, etched, planarized, and so forth to form features in and/or on a substrate. The features are arranged to form integrated circuits (ICs), MEMS, and other microelectronic structures.

Wet chemical processes are commonly used to form features on microelectronic substrates. Wet chemical processes are generally performed in wet chemical processing tools that have multiple processing chambers for combinations of cleaning, etching, electrochemical deposition, and rinsing. Electrochemical deposition processes include electrolytic deposition, in which current is applied to the substrate, and electroless deposition, where no external current is supplied to the substrate.

It is customary to include the ability to monitor the chemical constituents or chemical activity of an electrolyte that is being used in one of the aforementioned processes. This is done in order to control the concentrations of the chemical constituents of the electrolyte in such a way as to maintain consistent processing of multiple substrates as the electrolyte is used throughout its lifetime. Commonly, analytical techniques must be developed specifically for each component of an electrolyte in the particular combination and concentrations of constituents that are present in that particular electrolyte. The methods for monitoring the constituents of an electrolyte involve among others electroanalytical methods. Titration (also known as titrimetric and volumetric analysis) is a very common absolute method of quantitative chemical analysis to determine the concentration of an identified/known substance with a very good accuracy. Electrochemical analysis utilizes potential/current to reduce/plate and oxidize/strip a metal component onto/off of a Rotating Disc Electrode (RDE). Absorption spectrophotometry takes advantage of the different optical characteristics of different chemical species. By transmitting light through a sample and analyzing the transmitted intensity over a wide wavelength range, the concentration of a specific species can be determined. High-performance liquid chromatography (HPLC) works by separating and detecting single bath components. It analyzes organic additives, complexing agents, breakdown products and leached-in photoresist components.

Classically, a separate analytical method is utilized to represent the concentration of each known constituent within the electrolyte. It can be time-consuming and expensive to design the analysis techniques or methods using electroanalytical, HPLC, titration, NIR Spectroscopy techniques, etc. for each of the constituents of an electrolyte. Furthermore, some commercial additives have two or more components and it may not be possible to separate them without prior knowledge of the chemical species. Monitoring of each of the chemical constituents of these electrolytes can be complex due to the multiple interactions that can occur between the constituents as their respective concentrations change and as the electrolyte ages. Aging of the electrolyte may result in the breakdown of one or more of its constituents due to oxidation, reduction, or catalytic activity, or it may involve interactions with the hardware or substrates that come into contact with the electrolyte over its lifetime, or other contamination.

Thus, there is a need for a device or a system which can allow the monitoring and controlling of electrolyte components during High Volume Manufacturing (HVM), in clean room environment and within a single structure. Further, the device or the system should be adaptable to different analyticaltechniques. The invention described herein addresses the above-described needs.

### SUMMARY OF THE EMBODIMENTS

In one aspect of the invention, a system for monitoring and controlling the quality of the solution(s) used for processing microelectronics substrate of a microelectronic substrate is disclosed. The system is modular, flexible, scalable and configured to be connected with similar systems to form a larger system. The system allows full access to the data collected and generated by the measurements and analytical methods. This enables better characterization, troubleshooting, and process improvement.

In one aspect of the invention, the system comprises a housing having sealed doors, each of the sealed doors having a front side and a back side. The system also comprises one or more wet parts cabinets configured on the front side of each of the sealed doors, wherein each of the wet parts cabinets is divided into a plurality of clusters and occupy one or more of chemical workstations which are configured to execute one or more analytical applications. The system further comprises one or more electrical cabinets configured on the back side of each of the sealed doors, wherein each of the electrical cabinets is configured to comprise electrical components for controlling the operation of the workstations. The system also comprises one or more chemical cabinets for storing and providing the chemicals required for analytical applications running through the workstations and an interface for connecting with one or more of computing devices, wherein the electroanalytical applications can be monitored and controlled through the computing devices.

As appropriate, the system is configured to maintain a negative pressure in the wet parts cabinet and an overpressure in the electrical cabinet.

As appropriate, the system is flexible to increase or decrease the number of occupied clusters.

As appropriate, the system is modular in nature and the chemical workstations may be installed as modular workstations for executing different analytical methods.

As appropriate, the system is configured to be connected with similar systems to form a larger system for executing the electroanalytical applications.

As appropriate, the wet parts cabinet comprises a Lego-like structure having standard chemical and analytical modules installed on it.

As appropriate, the execution process and analysis results of the analytical applications running through the workstations can be displayed on a screen of the computing device.

As appropriate, an error in the execution of the analytical applications running through the workstations can be rectified through the computing device.

As appropriate, the workstations may comprise one or more of a Titration workstation, an Electrochemical Analysis-CVS workstation, a High Pressure Liquid Chromatography (HPLC) workstation and a Spectrophotometry workstation.

According to another aspect of the invention, the system comprises a memory unit configured to store configurations and parameters of the analytical applications running through the workstations.

According to further aspect of the invention, the system comprises a capacity top tray configured to provide support to an upper structure of the modular system including the Wet parts cabinets and the electrical cabinets.

According to yet another aspect of the invention, the system comprises a capacity bottom tray configured to provide support to a bottom structure of the system including the chemical cabinets.

As appropriate, the electrical cabinet is configured to control the power provided to the workstations ensuring controlled execution of the applications. The electrical cabinet is further configured to provide interconnectivity between the workstations for executing the analytical applications.

As appropriate, each of the sealed doors comprises a seal strip on its parameter for sealing the wet parts cabinet from the electrical cabinet while the sealed door is closed.

As appropriate, the seal strip is configured to maintain different pressure conditions in the wet parts cabinet and the corresponding electrical cabinet. The seal strip maintains negative pressure in the wet parts cabinet to prevent leakage of chemicals to the electrical cabinet and from the system. The seal strip also maintains an overpressure in the electrical cabinet to avoid intrusion of chemical vapours and dust.

According to another aspect of the invention, the system comprises a ventilation exhaust for sucking out the air from the wet parts cabinet and the chemical cabinet.

As appropriate, the housing comprises transparent or semi-transparent external doors for an operator to view the wet parts cabinets, wherein the doors are designed as foldable dual section doors to decrease footprint while opening.

According to yet another aspect of the invention, the system comprises a pressure sensor configured to detect pressure values in the wet parts cabinets and the chemical cabinets. An operation indicator displays the pressure sensor values in a color-coded format.

According to another aspect of the invention, the system further comprises pressure control systems in the wet parts cabinets and the chemical cabinets.

According to further aspect of the invention, the system comprises a leakage sensor configured to detect the leakage of liquids from the wet parts cabinet. the leakage condition is displayed though an optical indicator on the leakage sensor in a color-coded format.

As appropriate, the chemical cabinets are provided as retractable shelfs to facilitate convenient loading/unloading of the chemicals.

### BRIEF DESCRIPTION OF THE FIGURES

For a better understanding of the embodiments and to show how it may be carried into effect, reference will now be made, purely by way of example, to the accompanying drawings.

With specific reference now to the drawings in detail, it is stressed that the particulars shown are by way of example and for purposes of illustrative discussion of selected embodiments only and are presented in the cause of providing what is believed to be the most useful and readily understood description of the principles and conceptual aspects. In this regard, no attempt is made to show structural details in more detail than is necessary for a fundamental understanding; the description taken with the drawings making apparent to those skilled in the art how the various selected embodiments may be put into practice. In the accompanying drawings:

FIG. 1 illustrates the front view of a system 100 configured to monitor and control the electrochemical techniques according to an aspect of the invention;

FIG. 2A illustrates the outer dimensions of a “dual-cluster” device 200a according to an exemplary embodiment of the invention;

FIGS. 2B and 2C illustrate schematic views of the dual-cluster devices 200b and 200c according to other aspects of the invention;

FIG. 2D illustrates schematic views of a single-cluster device 200d according to another aspect of the invention;

FIG. 3A illustrates an open structure view of a dual cluster process control device comprising wet parts cabinet configuration in accordance with an embodiment of the invention;

FIG. 3B illustrates an open structure view of a dual cluster process control device showing retractable shelfs;

FIG. 4 illustrates an open structure view of the process control device with opened module door;

FIG. 5A illustrates a schematic front view of the process control device 500 showing the various structural components;

FIG. 5B illustrates a schematic top view of the process control device showing electrical cabinet;

FIG. 6A illustrates open structure views of a process control device comprising single cluster wet parts cabinet configurations in accordance with an embodiment of the invention;

FIG. 6B illustrates a schematic view of a dual cluster wet parts cabinet configuration in accordance with another embodiment of the invention;

FIG. 7 illustrates open structure views of a process control device comprising single cluster wet parts cabinet configurations in accordance with another embodiment of the invention;

FIG. 8 illustrates electric cabinet 800 behind the module door of the process control device;

FIG. 9 illustrates a multi-bath Wafer Level Packaging (WLP) Plater setup connected to a dual cluster system in accordance with an embodiment of the invention;

FIG. 10 illustrates an operation indicator on the process control device;

FIGS. 11 and 12 illustrate a leakage sensor in the wet parts cabinet;

FIG. 13 illustrates a fan under cover on the top of the device frame;

FIGS. 14A, 14B and 14C illustrate Titration workstation, Electrochemical Analysis -CVS workstation and High Pressure Liquid Chromatography (HPLC) workstation, respectively;

FIG. 15 illustrate a Bar code/QR code reader on the process control device; and

FIG. 16 illustrates an exemplary system for implementing various aspects of the invention.

### DESCRIPTION OF THE SELECTED EMBODIMENTS

Aspects of the present disclosure relate to a device or a system which can monitor and control the components of the electrolyte solution within a single structure. The system is flexible, scalable and tailored to the applications. The system comprises a Lego-like structure allowing different chemical analytical modules installed on it. Various metrology units may be installed as modular workstations for executing different analytical methods. Each workstation may perform defined tasks, such as analyzing, sampling, standard creation, etc. These workstations may be equipped as often as possible with identical devices and assemblies for simplified maintenance. The system might be a Wafer Level Packaging (WLP) Platform highly customizable and supporting multiple metals.

In particular embodiments of the system, the system may allow process control through liquid replenishment, solid replenishment (Direct Metal Replenishment (DMR)), Bleed & Feed to keep break down products and/or impurities below a desired range and might be used to Bleed & Replenish for ECP chemistries.

In other embodiments of the system, the system may comprise a software for storing the configurations and parameters of the workstations. The processes of the workstations may be synchronized as per the applications. The software also enables updating, repair and maintenance of the workstations independently without effecting the operation of other modules.

As required, the detailed embodiments of the present invention are disclosed herein; however, it is to be understood that the disclosed embodiments are merely examples of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

It is particularly noted that the systems and methods of the disclosure herein may not be limited in its application to the details of construction and the arrangement of the components or methods set forth in the description or illustrated in the drawings and examples. The systems and methods of the disclosure may be capable of other embodiments, or of being practiced and carried out in various ways and technologies.

Alternative methods and materials similar or equivalent to those described herein may be used in the practice or testing of embodiments of the disclosure. Nevertheless, particular methods and materials described herein for illustrative purposes only. The materials, methods, and examples not intended to be necessarily limiting. Accordingly, various embodiments may omit, substitute, or add various procedures or components as appropriate. For instance, the methods may be performed in an order different from described, and that various steps may be added, omitted or combined. In addition, aspects and components described with respect to certain embodiments may be combined in various other embodiments.

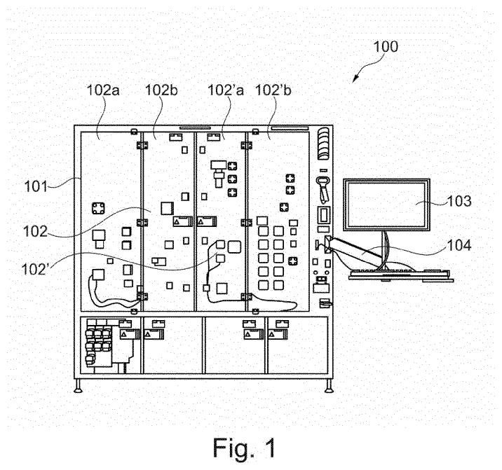

Reference is now made to FIG. 1 which illustrates the front view of a system 100 configured to monitor and control the electrochemical techniques according to an aspect of the invention. The system 100 comprises a process control device having a housing/frame 101 divided into number of compartments/cabinets and comprising (analytical) clusters (dual cluster configuration in the present example). The housing 101 has two transparent or semi-transparent external protective doors 102 and 102′ that might be designed as foldable dual section doors (102a, 102b, 102′a and 102′b) to decrease footprint while opening. Protective doors preferably are not sealed and enables limited air circulation from the ambient. Each cluster is configured to occupy a number of modular workstations for executing different analytical methods as will be described further below. The housing 101 is flexible and scalable and might to occupy lesser or more number of analytical clusters (further clusters). Protective doors (102a, 102b, 102′a and 102′b) could be removable from its hinges for service/maintenance procedure. Protective doors (102a, 102b, 102′a and 102′b) could be provided by opening detectors (switches) that shut-down fully or partially the system operation for safety reasons.

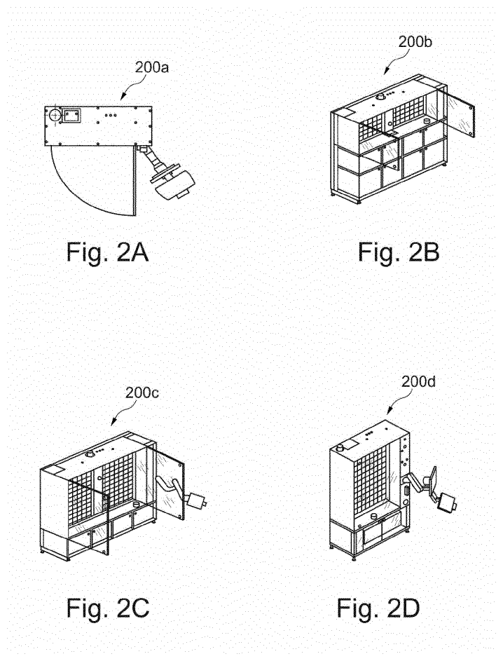

FIG. 2A illustrates the outer dimensions of a housing of dual cluster device 200a according to an exemplary embodiment of the invention. The device 200a is shown to have the structure size of 1.27×0.56 meters. FIGS. 2B and 2C illustrate schematic views of the dual cluster devices 200b and 200c with opened external protective doors according to other aspects of the invention. FIG. 2D illustrates schematic views of a single cluster device 200d according to another aspect of the invention. It should be clearly understood that the above-mentioned dimensions and structural components are exemplary in nature and should not limit the scope of the invention. The device 101 is flexible to occupy any required number of clusters as per the applications.

Referring back to FIG. 1, the device 101 is connected to a human machine (HM) interface 103 via a connecting medium 104. The HM interface 103 may be a communication device such as a personal computer, a laptop, a mobile phone, a tablet, a paging device and the like. The communication device 103 may be connected to the process control device 101 via a wired or a wireless connecting medium 104. The wired medium may comprise Ethernet cables, fiber-optic cables, etc. The wireless medium may comprise one or more of Internet, Bluetooth network, Wired LAN, Wireless LAN, WiFi Network, Zigbee Network, Z-Wave Network or Ethernet Network. The HM interface 103 may be placed near to the process control device 101 as shown in FIG. 1. Alternatively, the HM interface 103 may be placed at a location remote from the process control device 101. An HM interface may be connected to more than one process control device enabling a user to control different process control device through the same communication device. In a further embodiment, two or more HM interfaces may be connected to a single process control device enabling multiple operators to monitor and control the operations of the process control device.

The data of various electrochemical and analytical processes executed in the workstations, their chemical compositions and concentrations, desired and actual ranges, running conditions including errors and failures, replenishment needs, processes time (elapsed and remaining times), analysis results, etc. are transferred from the process control device 101 to the communication device 103. The communication device 103 may be configured to comprise a display screen enabling the operators to have full access to the data collected and generated by the measurements and analytical methods running in various workstations of the process control device 101. For example, the screen may provide information of the liquids used in an electrochemical process including their current levels, lower and upper threshold limits, deviation from the desired ranges, contamination levels, etc. The communication device 103 also enable processes to be controlled either directly through commands from the communication device 103 or by accessing the workstations of the process control device 101. The communication device 103 may also enable characterization, troubleshooting, and process improvement.

According to one aspect of the invention, the system 100 provides the advantage of occupying less footprint as it can be installed close to the wall and fully accessed from the front side during operation. All the internal compartments/modules of the device 101 can be accessed from the front side. The back side of the device 101 could be closed after assembling or repair of the workstations. The device can also be serviced or checked from the front side providing easy access to the operators.

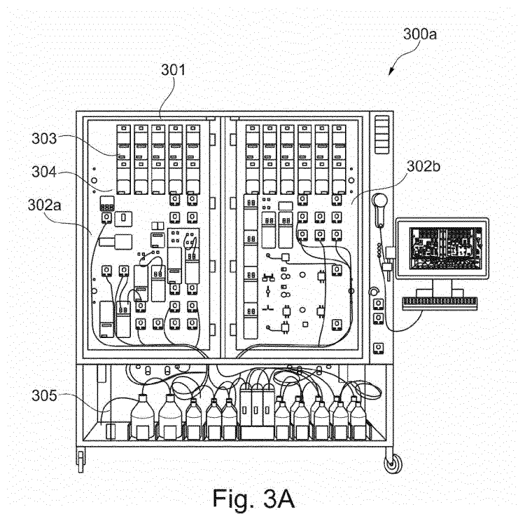

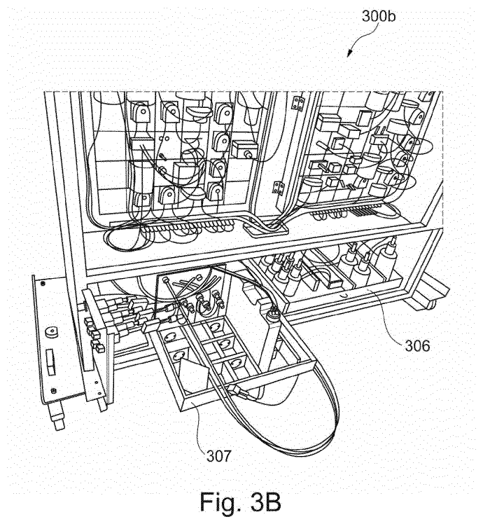

Referring to FIG. 3A which illustrates an open structure view 300a of the process control device 301 comprising dual cluster or double wet parts cabinet configuration in accordance with an embodiment of the invention. The device 301 comprises two (analytical) clusters formed by module doors 302a and 302b. The module doors 302a and 302b comprise frames divided into multiple sub-clusters 303 having standard dimensions, e.g. 10×10 cm. Specific metrology or operational units could occupy area of one or more of these sub-clusters 303. These metrology units can be formed as “separate” workstations from standard sub-modules having dimensions of single or multiple sub-clusters that could be assembled on the frame of module door(s) 302a and 302b. In a particular embodiment of the invention, the weight of each single sub-cluster module is limited by 1 KG-total weight of metrology modules not exceeding, e.g., 60 Kg for a 6×10 cluster (keep stable Center of mass of the entire system). The empty sub-cluster(s) 304 are covered by removable plate(s) from chemically resistant material (e.g., plastic), assembled on the frame of module door and sealed.

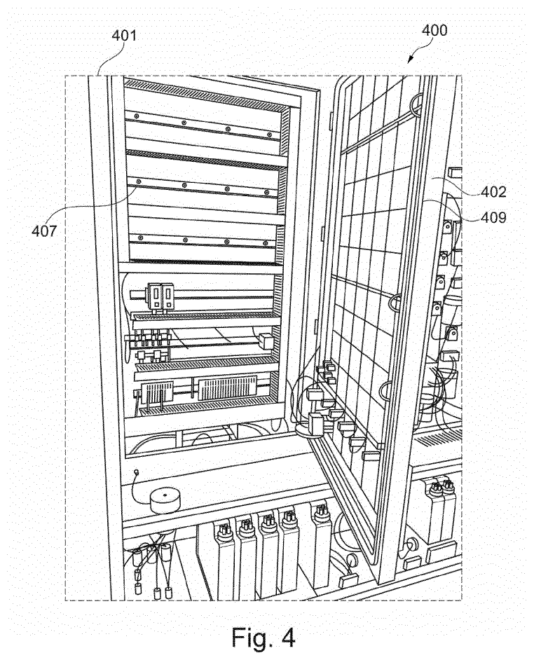

Referring to FIG. 4 which illustrates an open structure view 400 of the process control device 401 with opened module door 402. Behind the module door 402 of Wet parts cabinet-compartment comprising chemical modules is located an electrical cabinet 407, including mainly low voltage electronic/electric modules (controllers, etc.)—illustrated are partially assembled low voltage modules.

Module door 402 has (rubber/silicon) seal strip 409 on its perimeter providing sealing the wet parts cabinet from the electrical cabinet while the module door 402 is closed.

The sealing 409 prevents contaminating electronic/electric modules by chemicals by creating different pressure conditions in these two compartments-under-pressure (relative to ambient) in wet parts cabinet and over-pressure in electrical cabinet.

The electrical cabinet 407 comprises low voltage electronic/electric modules (controllers, etc.), electric connectors in form of copper or optical cables, voltage/current stabilizers, regulators, protection circuits, switches, temperature and pressure controllers, etc. The electric cabinet 407 is configured to interconnect various clusters of the workstations. The electrical cabinet 407 also provides interconnectivity between different workstations for executing the applications. The electric cabinet 407 controls the power provided to the various workstations ensuring controlled execution of the applications.

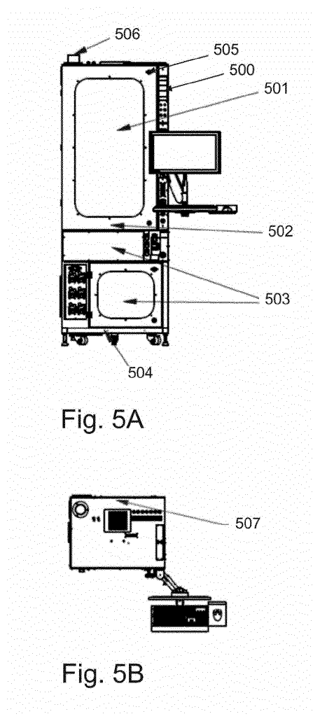

The Wet parts cabinet preferably may contain negative pressure relative to ambient to avoid leakage of chemical to the electrical cabinet and from the system to the ambient. During operation, the operator is protected from chemical leakage by monitored protective doors. In case of leakage, the liquids are collected in a monitored secondary containment of the chemical cabinet 503 for further evacuation as illustrated in FIG. 5.

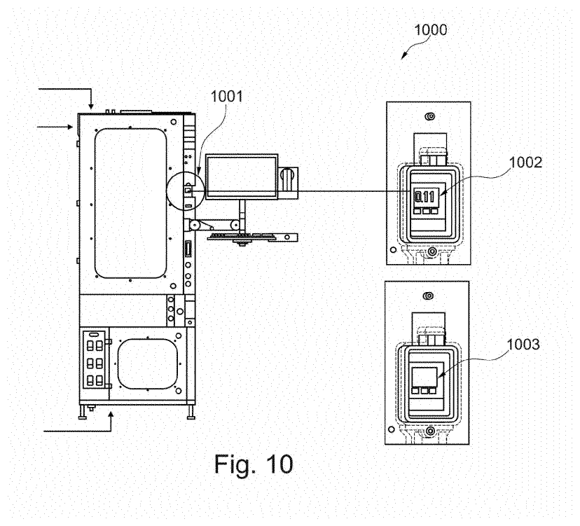

The air in the wet parts cabinet is continuously sucked out and replaced by outside air through an exhaust available on the device. Referring to FIG. 5A, an exhaust 506 could be provided at the top of the device 500 (arrows in FIG. 10 show side and bottom locations of exhaust). The exhaust of the system is connectable to the exhaust system of FAB. The exhaust ventilation 506 is connected with the wet parts cabinet 501 and the chemical cabinets 503. In a preferred embodiment, the air in these cabinets is exchanged at least three times per minute. The pressure in the exhaust pipe of the ventilation 506 is detected by a pressure sensor. In particular embodiment, normally a pressure of 75-120 m 3/h (60-150 Pascal) is maintained at the sensor. If the pressure difference between the ambient pressure and the pressure in the exhaust pipe of the ventilation 506 is out of range, a pressure sensor detects it and displays on an operation indicator 505.

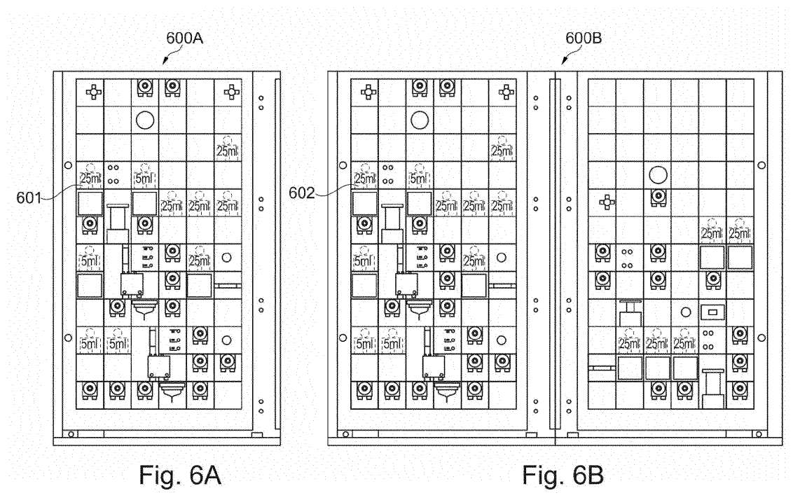

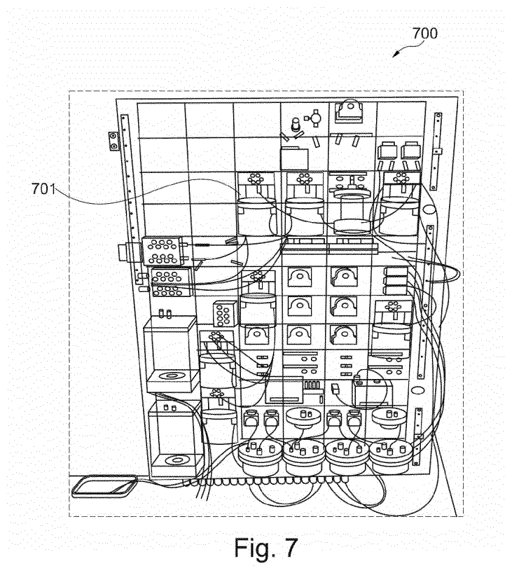

FIG. 6B illustrates a schematic view of a dual cluster or double wet parts cabinet configuration having 6×12 clusters 602. FIGS. 6A and 7 illustrate open structure views 600A and 700, respectively, of the process control device comprising single wet parts cabinet configurations having 6×12 clusters 601 and 701 in accordance with other embodiments of the invention.

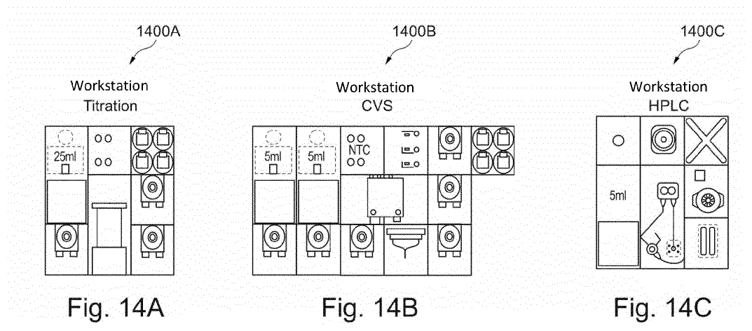

The workstations may be formed on the various sub-clusters for performing different electrochemical and analytical processes as shown in FIGS. 14A, 14B and 14C. Each workstation performs defined tasks, such as analyzing, sampling, standard creation, etc. depending upon the application. For example, a Titration workstation 1400A may be formed from the clusters on the module door. Titration is a very common absolute method of quantitative chemical analysis to determine the concentration of an identified/known substance with a very good accuracy. The various Titration workstations may include an Acid-Base Titration WorkStation, Photometric Titration (PHT) WorkStation, Stability Index WorkStation, Reduction/Oxidation WorkStation, etc.

In an alternative embodiment, an Electrochemical Analysis-CVS workstation 1400B may be formed from the clusters on the module door. The Electrochemical Analysis technique utilizes potential/current to reduce/plate and oxidize/strip a metal component onto/off of a Rotating Disc Electrode (RDE). The current-voltage curves are measured and evaluated to get the analysis results. The various Electrochemical Analysis workstations may include an Accelerator/Leveller workstation, a Suppressor workstation, Inorganic Stability (Pb), workstation, etc.

In a further embodiment, a High Pressure Liquid Chromatography workstation 1400C may be formed from the clusters on the module door. HPLC works by separating and detecting single bath components. It analyzes organic additives, complexing agents, breakdown products and leached-in photoresist.

During operation, depending upon the respective workstation, liquids (chemicals, water, etc.) are moved into/within/out the wet parts cabinet. The liquids may be temporarily stored in containers, mixed, heated or cooled as per the requirements. All the liquids might be monitored and analyzed via various sensors located in the process control device. The different workstations could be equipped as often as possible with standard identical devices and assemblies for simplified maintenance. The process control device may also comprise a software for executing, controlling and modifying the processes on the process control device. The device configurations/parameters are stored in a memory of the process control device. The software also synchronizes the sequences within the clusters of each workstation and within different workstations. The software also allows the operator to add, remove, and modify the sequences executing in workstations. The software may also allow the operator to add, remove, and modify the applications executing in workstations.

Referring back to FIG. 5A which illustrates a schematic view of the process control device 500 showing the various structural components. The wet parts cabinet 501 is located behind the front doors comprising chemical modules (workstations), pipes, etc. assembled on the frame divided into standard sub-clusters. The device 500 comprises chemical cabinets 503 storing the various chemicals required for different processes running through workstations and/or replenishment. The chemical cabinets 503 supply chemicals to the workstations as per the required applications and timelines. As illustrated in FIG. 3, the chemical cabinet 305 stores the required chemicals in holding apparatuses (e.g. containers, bottles). These holding apparatuses may be of any suitable material comprising, but not limited to, plastic, glass, steel, or any other metal which does not react and contaminate with the stored chemical. Preferably, in order to facilitate the convenient loading/unloading the chemical cabinet is provided by retractable shelf(s) 306 and 307 that allows convenient access and organization as illustrated in FIG. 3B.

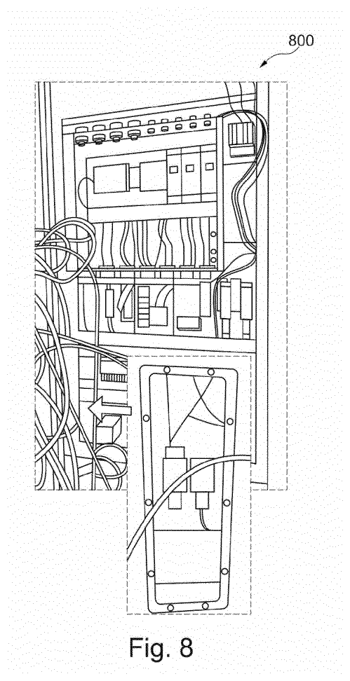

FIG. 8 illustrates electric cabinet 800 behind the module door of the process control device. The electric cabinet 800 comprises low voltage electronic/electric modules (controllers, etc.), electric connectors in form of copper or optical cables, voltage/current stabilizers, regulators, protection circuits, switches, temperature and pressure controllers, etc. The electric cabinet 800 is configured to interconnect various clusters of the workstations. The electric cabinet 800 also provides interconnectivity between different workstations for executing the applications. The electric cabinet 800 controls the power provided to the various workstations ensuring controlled execution of the applications.

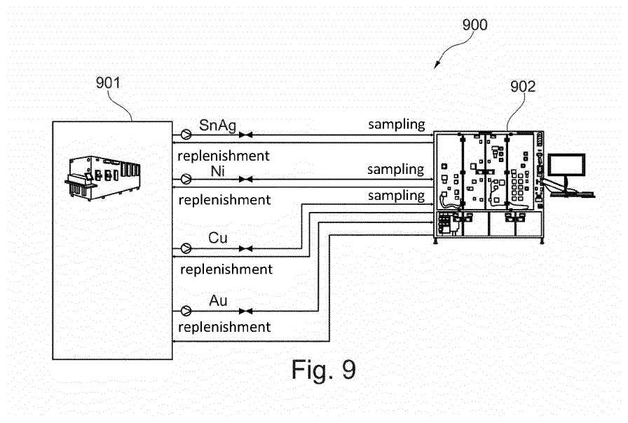

FIG. 9 illustrates a multi-bath Wafer Level Packaging (WLP) Plater setup 901 connected to dual-cluster system 902. The WLP Plater setup 901 might comprise various tanks for executing the process of sampling and optionally replenishment with the system 902. The setup 901 may contain a pre-wet tank, a rinse tank, Tin-Silver, Nickel, Copper and Gold plating cells (tanks). The system 900 enable fully automated process control analysis and dosing integrated metrology. The system 900 also enable multiple metals on the same plater running four STDs and slipstreams.

Referring to FIG. 10, the exhaust value information is displayed on the operation indicator 1001 which might display the information in a color-coded format. For example, the exhaust value within the range is displayed through ‘Green’ color 1002, while the exhaust value out of range is displayed through ‘Red’ color 1003. The negative pressure monitoring is done by the pressure sensor situated in the exhaust pipe.

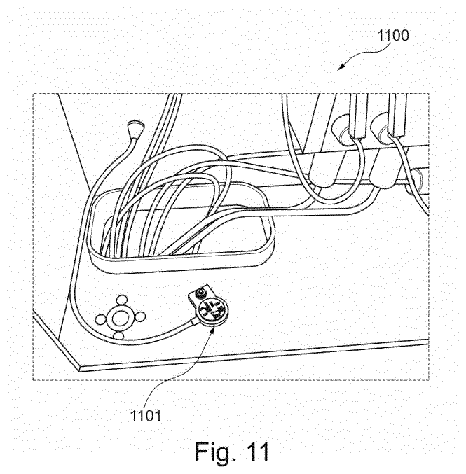

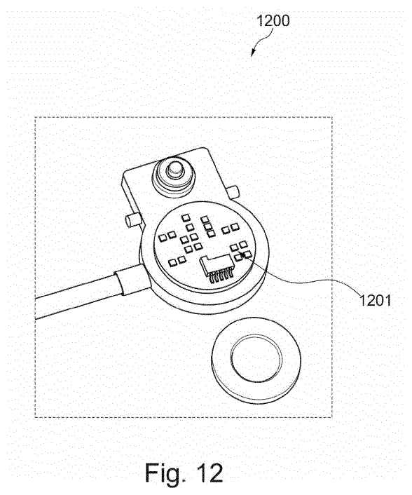

Referring now to FIG. 11 which illustrates a leakage sensor 1101 in wet parts cabinet. The leakage sensor 1101 detects the leakage of liquids (chemicals, water, etc.) from the wet parts cabinet. As long as no liquid is detected by the leakage sensor 1101, a ‘Green’ optical signal is displayed. If the leakage sensor 1101 responds, the optical signal is ‘Red’ as shown in FIG. 12. On the display of ‘Red’ signal, one or more of the following action points might be executed automatically:
The actuator circuit is switched off immediately.
No chemicals are pumped in the workstations of the wet parts cabinet.
The external supply lines for filling bulk containers are closed.
All current analysis and replenishment jobs are aborted.
The signal lights up red and the horn sounds.
A signal output informs an external receiver that the process control device is no longer ready for use. The signal output may be displayed on the connected communication device.

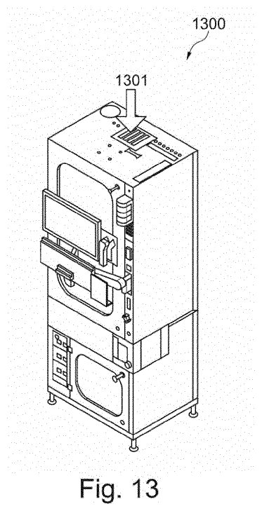

In a particular embodiment of the invention, a fan may be provided on the device to create overpressure in the electrical cabinet. FIG. 13 illustrates the position 1301 of a fan under cover on the top of the device 1300 frame. The fan provides overpressure in the electrical cabinet to avoid intrusion of chemical vapors/dust. The rotation speed of the fan may be displayed on a device 1300 screen or the communication device screen or on a separate indicator. A fault in the fan may also be displayed on the device 1300 or the communication device screen or alarm signal lamp(s). A protective guard prevents touching the running fan. CDA pressure control (detector/controlling electronics) could be located in the cabinet. In particular embodiments of the system, the system may allow process control through various steps including, but not limited to, liquid replenishment, solid replenishment (Direct Metal Replenishment (DMR)), Bleed & Feed to keep break down products and/or impurities below a desired range and Bleed & Replenish for ECP chemistries.

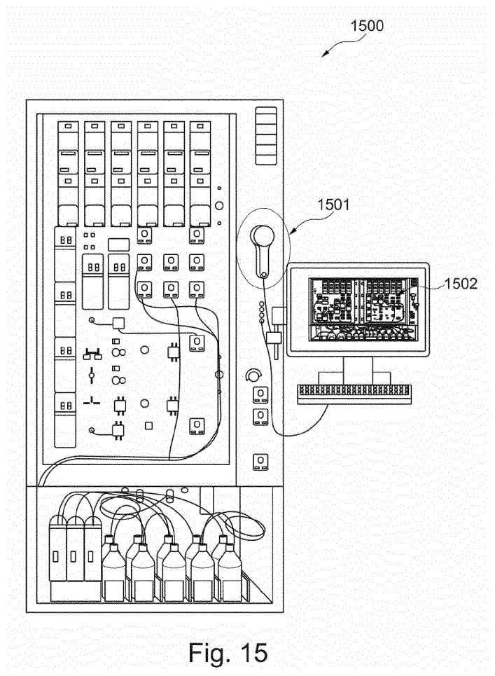

The process control device may comprise a Bar code/QR code reader 1501 as shown in FIG. 15 to identify each chemical container before connecting the device to the analytic and/or dosing system. Chemicals can be used for analytical or replenishment purposes. The status of the chemical containers may be displayed on the screen 1502 of the communication device. The expiration dates of each chemical can be read and stored in a chemical manager and may be displayed on the screen 1502 of the communication device. The system may also comprise level sensors for minimum and below minimum levels for each chemical container.

In case of replenishment, the desired replenishment volume of the chemicals is correctly determined in order to reach the target concentration in the bath. The liquid and solid replenishment (Direct Metal Replenishment (DMR)) is performed according to Amp time, Product-wafer passes, Elapsed time and Analysis results. Bleed & Feed is performed to keep break down products and/or impurities below a desired range. It can be executed like replenishment based on Amp time, Product—wafer passes, Elapsed time and Analysis results. Bleed & Replenish for ECP chemistries (low-alpha solder, Cu, Ni) is also performed according to Amp time, Product—wafer passes, Elapsed time and Analysis results.

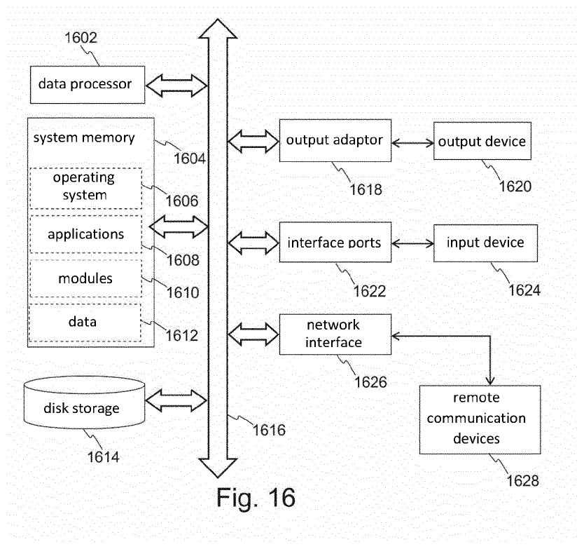

FIG. 16 illustrates an exemplary system 1600 for implementing various aspects of the invention. The system 1600 includes a data processor 1602, a system memory 1604, and a system bus 1616. The system bus 1616 couple system components including, but not limited to, the system memory 1604 to the data processor 1602. The data processor 1602 can be any of various available processors. The data processor 1602 refers to any integrated circuit or other electronic device (or collection of devices) capable of performing an operation on at least one instruction, including, without limitation, Reduced Instruction Set Core (RISC) processors, CISC microprocessors, Microcontroller Units (MCUs), CISC-based Central Processing Units (CPUs), and Digital Signal Processors (DSPs). Furthermore, various functional aspects of the data processor 1602 may be implemented solely as software or firmware associated with the processor. Dual microprocessors and other multiprocessor architectures also can be employed as the data processor 1602.

The system bus 1616 can be any of several types of bus structure(s) including the memory bus or memory controller, a peripheral bus or external bus, and/or a local bus using any variety of available bus architectures known to those of ordinary skill in the art.

The system memory 1604 may include computer-readable storage media comprising volatile memory and nonvolatile memory. The non-volatile memory stores the basic input/output system (BIOS), containing the basic routines to transfer information between elements within the system 1600. The nonvolatile memory can include, but not limited to, read only memory (ROM), programmable ROM (PROM), electrically programmable ROM (EPROM), electrically erasable programmable ROM (EEPROM), or flash memory. The volatile memory includes random access memory (RAM), which acts as external cache memory. RAM is available in many forms such as static RAM (SRAM), dynamic RAM (DRAM), synchronous DRAM (SDRAM), double data rate SDRAM (DDR SDRAM), enhanced SDRAM (ESDRAM), SynchLink™ DRAM (SLDRAM), Rambus® direct RAM (RDRAM), direct Rambus® dynamic RAM (DRDRAM), and Rambus® dynamic RAM (RDRAM).

The system memory 1604 includes an operating system 1606 which performs the functionality of managing the system 1600 resources, establishing user interfaces, and executing and providing services for applications software. The system applications 1608, modules 1610 and data 1612 provide various functionalities to the system 1600.

The system 1600 also includes a disk storage 1614. Disk storage 1614 includes, but is not limited to, devices like a magnetic disk drive, floppy disk drive, tape drive, Jaz drive, Zip drive, LS-100 drive, flash memory card, or memory stick. In addition, disk storage 1614 can include storage media separately or in combination with other storage media including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM).

A user enters commands or information into the system 1600 through input device(s) 1624. Input devices 1624 include, but are not limited to, a pointing device (such as a mouse, trackball, stylus, or the like), a keyboard, a microphone, a joystick, a satellite dish, a scanner, a TV tuner card, a digital camera, a digital video camera, a web camera, and/or the like. The input devices 1624 connect to the data processor 1602 through the system bus 1616 via interface port(s) 1622. Interface port(s) 1622 include, for example, a serial port, a parallel port, a game port, and a universal serial bus (USB).

The output devices 1620 like monitors, speakers, and printers are used to provide output of the data processor 1602 to the user. Another example, a USB port may be used as an input device 1624 to provide input to the system 1600 and to output information from system 1600 to the output device 1620. The output devices 1620 connect to the data processor 1602 through the system bus 1616 via output adaptors 1618. The output adapters 1632 may include, for example, video and sound cards that provide a means of connection between the output device 1620 and the system bus 1616.

The system 1600 can communicate with remote communication devices 1628 for exchanging information. The remote communication device 1628 can be a personal computer, a server, a router, a network PC, a workstation, a microprocessor-based appliance, a mobile phone, a laptop, a tablet, a paging device, a peer device or other common network node and the like.

Network interface 1626 encompasses wire and/or wireless communication networks such as local-area networks (LAN) and wide-area networks (WAN). LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

While the preferred embodiment of the present invention and its advantages has been disclosed in the above detailed description, the invention is not limited there to but only by the scope of the appended claim.

As will be readily apparent to those skilled in the art, the present invention may easily be produced in other specific forms without departing from its essential characteristics. The present embodiments are, therefore, to be considered as merely illustrative and not restrictive, the scope of the invention being indicated by the claims rather than the foregoing description, and all changes which come within therefore intended to be embraced therein.

We claim:

1. A system (100, 500) for monitoring and controlling the processing of a microelectronic substrate, the system comprising:
a housing (101) having sealed doors (102, 102′), each of the sealed doors having a front side and a back side;
one or more wet parts cabinets (501) configured on the front side of each of the sealed doors, wherein each of the wet parts cabinets is divided into a plurality of clusters and occupy one or more of chemical workstations (1400A, 1400B, 1400C) which are configured to execute one or more analytical applications;
one or more electrical cabinets (507, 800) configured on the back side of each of the sealed doors, wherein each of the electrical cabinets is configured to comprise electrical components for controlling the operation of the workstations;
one or more chemical cabinets (503) for storing and providing the chemicals required for analytical applications running through the workstations; and an interface (104) for connecting with one or more of computing devices (103), wherein the analytical applications can be monitored and controlled through the computing devices.
wherein a negative pressure is maintained in the wet parts cabinet and an overpressure is maintained in the electrical cabinet.

2. The system of claim 1, wherein the system is flexible to increase or decrease the number of occupied clusters.

3. The system of claim 1, wherein the system is modular in nature and the chemical workstations may be installed as modular workstations for executing different electrochemical applications.

4. The system of claim 1, wherein the system is configured to be connected with similar systems to form a larger system for executing the analytical applications.

5. The system of claim 1, wherein the wet parts cabinet comprises a Lego-like structure having standard chemical and analytical modules installed on it.

6. The system of claim 1, wherein the interface comprises a wired interface, a wireless interface or a combination thereof.

7. The system of claim 1, wherein the execution process and analysis results of the analytical applications running through the workstations can be displayed on a screen of the computing device.

8. The system of claim 1, wherein an error in the execution of the analytical applications running through the workstations can be rectified through the computing device.

9. The system of claim 1, wherein the workstations comprise one or more of a Titration workstation, an Electrochemical Analysis-CVS workstation, a High Pressure Liquid Chromatography (HPLC) workstation and a Spectrophotometry workstation.

10. The system of claim 1 further comprises a memory unit configured to store configurations and parameters of the analytical applications running through the workstations.

11. The system of claim 1 further comprises a capacity top tray (502) configured to provide support to an upper structure of the system including the Wet parts cabinets and the electrical cabinets.

12. The system of claim 1 further comprises a capacity bottom tray (504) configured to provide support to a bottom structure of the system including the chemical cabinets.

13. The system of claim 1, wherein the electrical cabinet is configured to control the power provided to the workstations ensuring controlled execution of the applications.

14. The system of claim 1, wherein the electrical cabinet is further configured to provide interconnectivity between the workstations for executing the analytical applications.

15. The system of claim 1, wherein each of the sealed doors comprises a seal strip (409) on its parameter for sealing the wet parts cabinet from the electrical cabinet while the sealed door is closed.

16. The system of claim 15, wherein the seal strip is configured to maintain different pressure conditions in the wet parts cabinet and the corresponding electrical cabinet.

17. The system of claim 16, wherein the negative pressure is maintained in the wet parts cabinet to prevent leakage of chemicals to the electrical cabinet and from the system.

18. The system of claim 16, wherein the overpressure is maintained in the electrical cabinet to avoid intrusion of chemical vapours and dust.

19. The system of claim 18, wherein the overpressure is maintained in the electrical cabinet through a fan provided on an upper side of the system.

20. The system of claim 1 further comprises a ventilation exhaust (506) for sucking out the air from the wet parts cabinet and the chemical cabinet.
Claims 21-27.
